(19) United States
(12) Patent Application Publication
(10) Pub. No.: US 2025/0013145 A1
(43) Pub. Date: Jan. 9, 2025

(54) MICROCHANNEL PRINTING

(71) Applicant: Worcester Polytechnic Institute, Worceter, MA (US)

(72) Inventors: Pratap Rao, Northborough, MA (US); John S. Berg, Rochester, MA (US); Maryam M. Shalmani, Worcester, MA (US)

(21) Appl. No.: 17/971,393

(22) Filed: Oct. 21, 2022

Related U.S. Application Data
(60) Provisional application No. 63/272,302, filed on Oct. 27, 2021.
(60) Provisional application No. 63/271,100, filed on Oct. 22, 2021.

(51) Int. Cl. G03F 7/00; B41F 19/00; H05K 3/12

(52) U.S. Cl. CPC G03F 7/0002; B41F 19/005; B41F 19/007; H05K 3/1258; H05K 3/1275

(57) ABSTRACT

Nanoimprint lithography forms a microfeature array on a substrate responsive to inkjet printing techniques for high resolution printing of circuit elements and other features with highly accurate fidelity to predetermined boundaries. The microfeature array is defined by micropillars formed between intersecting microchannels in the substrate. The micropillars are responsive to a sequence of ink droplets in a highly controlled and predictable manner based on the droplet volume, droplet spacing and temperature. The flow of liquid ink is restrained by the micropillars for pinning the ink for avoiding uncontrolled ink flow as occurs on a flat surface. Subsequent layers of deposited ink tend to follow pining of previous layers, allowing an iterative buildup of layers for forming a trace of sufficient thickness and a high aspect ratio allowing traces extending above the depth of the microchannels for aiding communication with surface mount components.

### RELATED APPLICATIONS

This patent application claims the benefit under 35 U.S.C. § 119(e) of U.S. Provisional Patent App. No. 63/271,100, filed Oct. 22, 2021, entitled “SURFACE WITH MICROFEATURE ARRAY,” and U.S. Provisional Patent App. No. 63/272,302, filed Oct. 27, 2021, entitled “INK DEPOSITION ONTO MICROFEATURE ARRAY,” all incorporated herein by reference in entirety.

### STATEMENT OF FEDERALLY SPONSORED RESEARCH AND DEVELOPMENT

This patent application is based on research sponsored, in part, by Air Force Research Laboratory under agreement number FA8650-15-2-5401. The Government has certain rights in the invention.

### BACKGROUND

Recent developments in semiconductor and flexible electronics applications have observed a rapid increase in demands for lower cost, higher throughput, and higher resolution micro/nanofabrication techniques. This is due to the fact that conventional techniques such as electron beam lithography (EBL) have a low throughput for mass production and other alternatives such as extreme ultraviolet lithography and focused ion beam lithography are very costly, limiting feasibility.

Nanoimprint lithography (NIL) is a simpler, low-cost, and high-throughput alternative to micro- and nanofabrication. In the NIL process, a prefabricated mold containing an inverse of the desired patterns is pressed onto a resist-coated substrate to replicate the patterns via mechanical deformation. Hence, many replications may be produced from a single prefabricated mold using this method. As the NIL process is based on direct mechanical deformation, its resolution is not constrained to the limitations of light diffraction or beam scattering factors as observed in conventional nanolithography methods. Roll-to-roll (R2R) nanoimprint lithography (NIL) is a particularly desirable technique due to its high-throughput suitable for industrial-scale usage.

### SUMMARY

Nanoimprint lithography forms microchannels or an array of microchannels on a substrate responsive to ink printing techniques for high resolution printing of circuit elements and other features with highly accurate fidelity to predetermined boundaries. Ink is deposited into the microchannels and the flow of liquid ink is constrained by the walls of the microchannels. The microchannels are either in the shape of the circuit or pattern to be printed, or a microfeature array is defined by micropillars formed between intersecting microchannels in the substrate. The microchannels are responsive to a sequence of ink droplets in a highly controlled and predictable manner based on the droplet volume, droplet spacing and temperature. The flow of liquid ink is restrained by the microchannels for pinning the ink for avoiding uncontrolled ink flow as occurs on a flat surface. Subsequent layers of deposited ink tend to follow pinning of previous layers, allowing an iterative buildup of layers for forming a trace of sufficient thickness and a high aspect ratio allowing traces extending above the depth of the microchannels for aiding connection to surface mount components.

Configurations herein are based, in part, on the observation that digital printing techniques are often employed for precision deposition of liquid and solvent based substances onto a substrate. Unfortunately, conventional approaches to ink deposition suffer from the shortcoming presented by adequate flow control of liquid inks to adhere to a predetermined or intended flow pattern. Liquid inkflow follows a flow pattern on a flat surface that varies according to somewhat unpredictable principles, causing ink to “run” or flow indiscriminately across the surface. Accordingly, configurations herein substantially overcome the shortcomings of conventional ink droplets and sprayed or extruded inkjet mediums by providing microchannels or a microchannel array on a surface and a method for filling the microchannels using printed ink and inkjet mediums. The disclosed approach addresses the need for printing electrically conductive features (such as circuit traces and features for attaching electrical components) with higher resolution, larger thickness and aspect ratio, improved cross-section profile, improved edge definition, tighter dimensional tolerance, and higher adhesion.

In particular configurations, a method of printing circuit traces and components includes forming microchannels on a substrate or a microfeature array on a substrate based on intersecting arrays of microchannels, where the substrate retains micropillars defined by protruding substrate regions flanked by intersecting microchannels. A nozzle or print apparatus deposits a sequence of ink droplets onto or into the microchannels based on a trace pattern, in which each ink droplet having a volume of ink and a spacing from adjacent ink droplets, as well as a viscosity. The microchannels confine the flow of each ink droplet to a width of the trace pattern while meeting a flow of adjacent droplets in the sequence for forming a continuous trace having well-defined and controllable boundaries.

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a system context diagram of a nanoimprint lithography and printing system suitable for use with configurations herein;

FIG. 2A is a perspective schematic view of an example microchannel on a substrate as in FIG. 1;

FIG. 2B is a perspective schematic view of an example microfeature array on a substrate as in FIG. 1;

FIG. 3 shows an iteration of printed layers in a microchannel;

FIG. 4 shows a profilometry of microchannels of FIG. 3 for successive iterations of layers;

FIG. 5 shows flat surface printing of layers in contrast to FIG. 4;

FIG. 6 shows a profilometry of the layers of FIG. 5;

FIGS. 7A-7C show an effect of temperature on microfeature array printing as in FIGS. 1-4;

FIGS. 8A-8D show layers of silver ink forming a trace on a microfeature array; and

FIG. 9 shows a resistance of a trace printed as in FIGS. 8A-8D.

### DETAILED DESCRIPTION

The description below presents an example of a surface having microchannels and a method for filling the microchannels using printing. The microchannels are created in the substrate by nanoimprint lithography or another suitable method. The substrate having microchannels can be made from a range of materials. The microchannels can be imprinted into sheets of materials such as PET and polyimide, which are commonly used for printed electronics, or can be imprinted into coatings. Ink (of any type including graphic inks, conductive, resistive, or other functional inks) is printed into the microchannels by inkjet printing or similar fluidic printing process.

Conventional approaches rely on capillary action to promote or extend fluid flow, from a point of supply or deposition along a flow path for extending coverage. In contrast, configurations herein employ pillar structures and channels for directing fluid only to the deposited regions, and limit flow from a point of deposition for increased accuracy. In other words, conventional approaches extend or promote fluid (ink) flow from a deposition (print) source; configurations herein limit or restrict fluid flow to the point or region of deposition.

Configurations herein printed or deposit along the entire length the intended trace or pattern defined by the microchannel. This is unlike previous approaches for filling microchannels with ink, in which ink is only printed or otherwise filled into a reservoir connected to the microchannels, and is then pulled into the microchannels by capillary forces (i.e. by wicking). Extended capillary flow is required in conventional approaches to direct an extended ink flow from a deposition source. In the disclosed approach, printing of the ink along the entire length of the microchannels can be achieved using either digital or pattern-based printing methods, with appropriate alignment of the microchannels in the printing platform. The ink fills the microchannels when the floor and walls of the microchannel are receptive to the ink, i.e. if there is a sufficiently low ink contact angle with the floor and walls. Sufficient velocity and/or pressure of the ink can also facilitate filling of the microchannels.

In conventional approaches, relying on flat surface properties and/or capillary action, the ink tends to flow and spread out more than desired on the surface during printing, e.g. during inkjet printing. It can be difficult to print very small features, i.e. it places an upper limit on the print resolution. Higher print resolution (ability to print smaller features) is generally preferable. This is especially important for printing fan outs for surface mount of packaged and unpackaged ICs (Integrated Circuits) having a high pin/bump count with a small pitch between pins/bumps. Another drawback of conventional approaches is difficulty with printing thick and narrow features (i.e. having a high aspect ratio). Thicker and narrower features are desired to simultaneously achieve high electrical conductance within a smaller area footprint. This benefits conductive traces that need to carry high currents, and dense circuit board arrangements where circuit board “real estate” is limited. A further complication arises from instabilities such as bulging and pooling, which lead to printed features having nonuniform (rough or wavy) edges and poor control of dimensions (poor dimensional tolerance). Conventional approaches often require substrate electroplating or other chemical treatment to assist with proper trace formation.

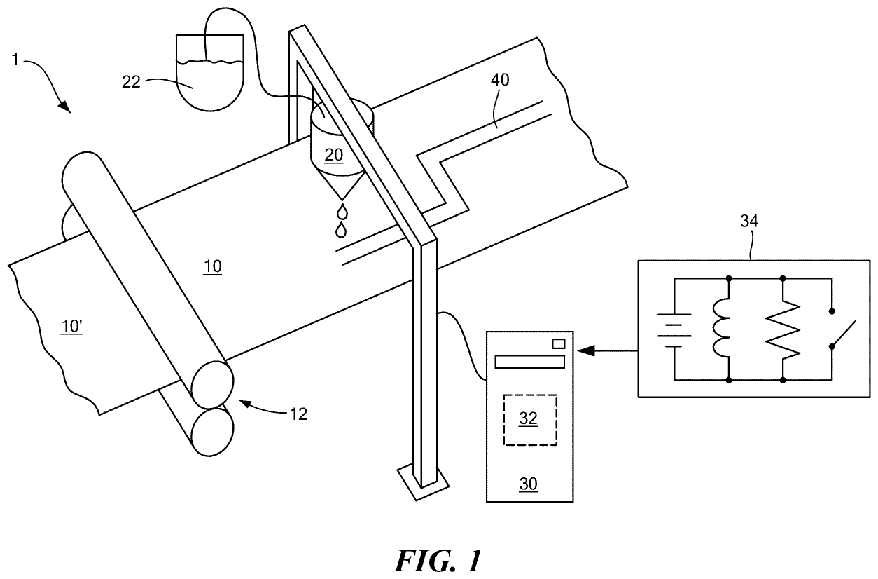

FIG. 1 is a system context diagram of a nanoimprint lithography and printing system 1 suitable for use with configurations herein. Nanoimprint lithography imprints microfeatures onto a substrate 10′. A Roller-to-Roller (R2R) nanoimprint apparatus 12 imprints the microfeatures to form the microfeature implant substrate 10. A print head 20 has an inkjet, extrusion, droplet, spray or other deposition mechanism for depositing droplets of a print liquid, or ink 22 from a suitable reservoir or cartridge. Any suitable print liquid may be employed depending on a solid composition to be deposited; often conductive ink is used for printing conductive traces, and include silver or other conductive particles in the ink 22. The print head 20 operates on a belt or track for lateral movement across the substrate. Lateral movement is coupled with forward and/or backward translation from the imprint rollers or other conveyor, allowing full digital control of the print head 20 to any location on the substrate 10. A control program 32 on a processor based control device 30 directs the movement according to a predetermined circuit plan 34 or trace path. The print head 20 is responsive to the control program 32 for printing a trace 40 of a length, width, and thickness according to the plan 34, now discussed further below.

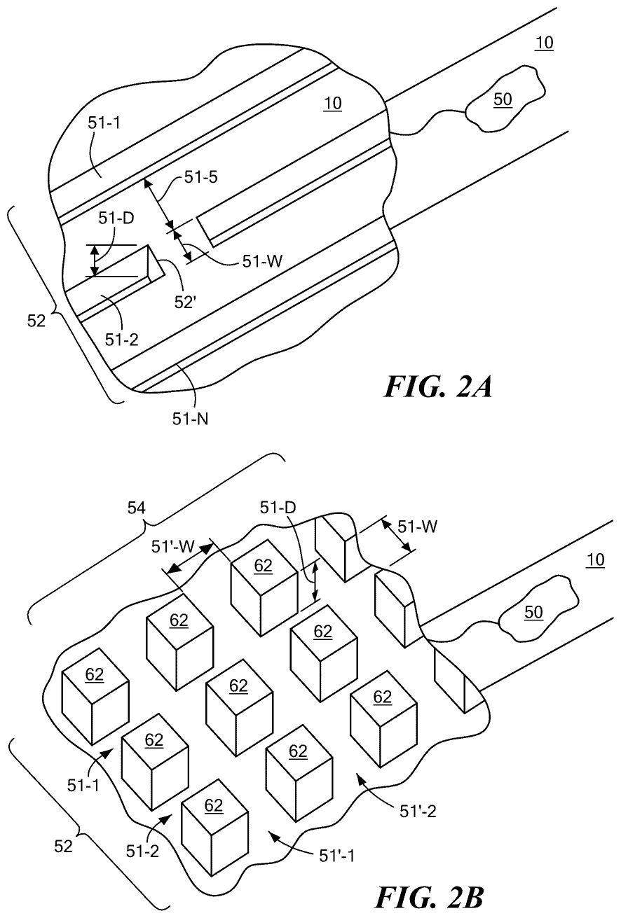

FIG. 2A is a perspective schematic view of an example microchannel on a substrate as in FIG. 1. Referring to FIGS. 1 and 2A, in a nanoimprint lithography development environment having a substrate as in FIG. 1 adapted for roll to roll microfeature imprinting, a microchannel set 52 includes one or more microchannels 51-1 . . . 51-N (51 generally) formed in response to the circuit plan 34 or other predetermined channel arrangement, often to follow the shape of a trace 40. Microchannels 51 in the substrate are formed with a depth 51-D and a width 51-W, and separated from other microchannels by a spacing 51-S, which may be the same as, wider or narrower than the microchannel width 51-W. Discontinuities 52′ in the microchannels are formed by undisturbed substrate regions forming walls in the microchannel, and are simply regions flush with the substrate surface 10. Any suitable number of microchannels may be formed; an array of intersecting microchannels 51 forms a set of microfeatures defining micropillars, now discussed in FIG. 2B.

FIG. 2B is a perspective schematic view of an example microfeature array on a substrate as in FIG. 1. Referring to FIGS. 1, 2A and 2Ba microfeature array 50 includes the substrate 10 adapted for nanoimprint lithography, a first microchannel set 52 including plurality of microchannels 51-1 . . . 51-N in the substrate extending in a first direction; and a second microchannel set 54 including a plurality of microchannels 51′-1 . . . 51′-N in the substrate extending in a second direction. Each set 52, 54 forms a parallel array of microchannels such that the microchannels of the first set intersect with the microchannels of the second set. The intersecting microchannels form the microfeature array 50 of micropillars 62, where each micropillar of the array of micropillars is defined by an intersection of the first and second sets of microchannels, typically at a right angle to form a rectangular or square polygonal shaped column as a microfeature on the substrate 10. Each micropillar 62 in the array 50 of micropillars is therefore defined by a protruding substrate region flanked by intersecting opposing pairs of microchannels 51 formed from lithographic evacuation of substrate material between the micropillars 62.

During the R2R (or other suitable) lithographic process, each microchannel 51 is formed having a width 51-W, 51′-W based on an intended width of a printed trace of ink onto the substrate. Multiple microchannels may contribute to the printed, or ink bearing region of a trace 40; the trace may call for multiple widths of microchannels 51/micropillars 62, but fidelity to maintain ink flow within the designated microchannels is preserved; the ink resists flow beyond the intended microchannels.

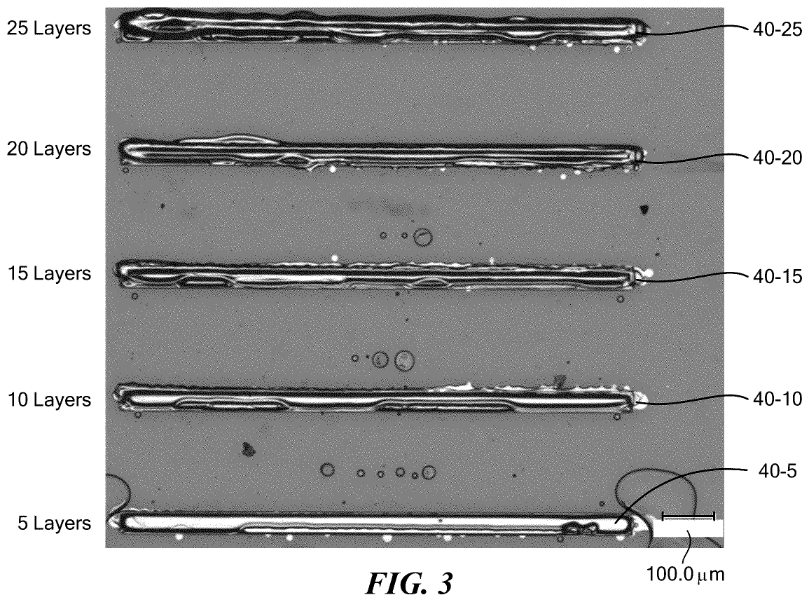

FIG. 3 shows an iteration of printed layers in a microchannel. Referring to FIGS. 1-3, the width 51-W of the microchannels 51 is based on a plurality of layers of ink deposited onto the substrate for forming the trace 40 of the intended width. The walls of the microchannel confine the ink and prevent it from flowing outwards, resulting in a printed shape and size that is tightly controlled by the microchannels 51.

Multiple layers of ink can be printed into the microchannel, to fill it to the desired depth. The ink is allowed to dry partially or completely in the microchannel between printing of successive layers, leaving behind the functional material to be deposited, often a conductive trace. Printing at an elevated substrate temperature can accelerate the drying of the ink and enable fast filling of the microchannels by multiple printed layers.

If the walls and floor of the microchannel are made more receptive or adhesive to the ink compared to the surface of the substrate, or if the surface of the substrate is made to repel the ink, then it is possible to achieve complete filling or even over-filling of the ink in the microchannel, so that the final dried material in the microchannel is flush with the surface of the substrate, or even protruding above the surface. This is beneficial for attachment of surface mount electrical components to conductors filled in the microchannels.

Each microchannel, therefore, has a width 51-W and a depth 51-D based on the height of the micropillars 62. In particular configurations the width is at least 10 times the depth. Alternatively, the depth may be substantially greater for increasing an aspect ratio (height to depth), for example for thicker traces having a greater current carrying capacity. In a typical implementation, for example, 10× width to height is desirable but could be as high as 1:1 or greater. FIG. 3 shows microscope images of microchannels having width of 40 μm and depth of 4 μm, which have been filled by inkjet printing of conductive silver nanoparticle ink along the microchannel length. The inkjet drops have diameters of roughly 20 μm. 5, 10, 15, 20, and 25 layers of silver nanoparticle ink were printed with a spacing of 24 μm between drops at 70° C. surface temperature, forming respective traces 40-5, 40-10, 40-15, 40-20 and 40-25. FIG. 3 demonstrates that by printing 15 layers, the process is able to fully fill the microchannel, and printing 20 or 25 layers results in over-filling of the microchannel with minimal spread of the ink to the sides. That is, the ink remains largely confined to the same region defined by the channel, even though it may protrude over the channel 51/micropillar 62 and over the substrate 10 surface. This over-filling of the ink in the microchannels can be helpful for attaching surface mount electrical components to conductive traces formed by filling conductive ink in the microchannels.

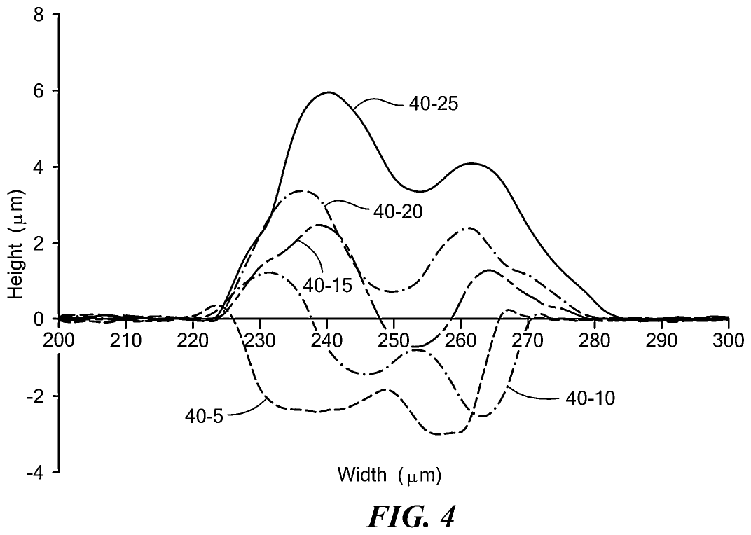

FIG. 4 shows a profilometry of microchannels of FIG. 3 for successive iterations of layers. In the cross section profiles of FIG. 1, each microchannel has a width and a spacing of ink droplets, such that the spacing is typically between 0.5 and 3 times the width. The full trace 40 is formed from iterative application of ink layers, and may be such that the trace having a height greater than a depth of the microchannels and extends proud of a flush surface defined by a top of the micropillars 62, also the same as the substrate 10 surface prior to channel formation. In FIG. 4, trace 40 height (or depth) is shown for iterative layer application for each trace 40-5, 40-10, 40-15, 40-20 and 40-25, where the zero height is defined by the substrate surface.

Microchannels 51 having much greater depth 51-D and aspect ratio can also be created by nanoimprint lithography or other methods using various processes. This approach of filling ink into microchannels would also apply to such deeper and higher-aspect-ratio channels.

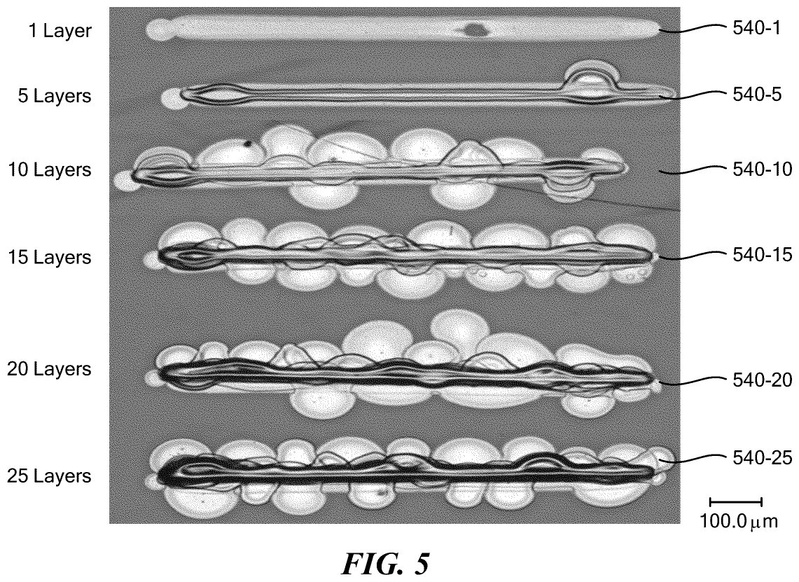

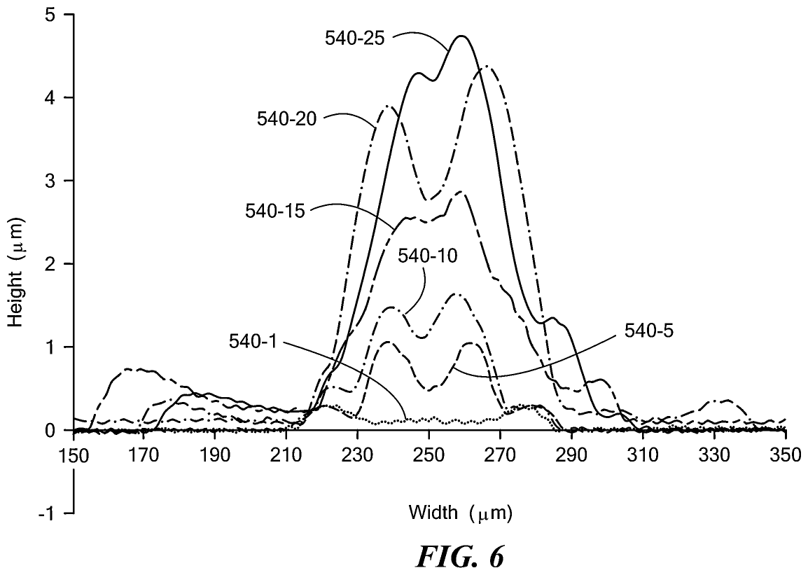

FIG. 5 shows flat surface printing of layers in contrast to FIG. 4, and FIG. 6 shows a profilometry of the layers of FIG. 5. Conversely, if the same ink is printed in the same manner onto the flat surface without the microchannels 51, the results are considerably less controlled. The first layer of ink forms a trace 540-1 that is around 80 μm wide, which is already 2× as wide as the microchannel. 5 layers of ink in trace 540-5 do not widen the original trace substantially. However, 10 layers forming trace 540-10, and additional layers in traces 540-15, 540-20 and 540-25 cause the ink to spill out to the sides, greatly widening the trace even further, likely forming a conductive path ripe for fracture or short circuits with adjacent conductive structures. FIG. 6 illustrates the profilometry of the printed traces 540-1 . . . 540-25 in FIG. 5, showing the cross-sectional profile and extent of spreading of the ink.

The nanoimprint lithography applied to the substrate 10 surface therefore forms an array of microfeatures with regular size, shape and spacing defining the micropillars 62, which are created by nanoimprint lithography or another suitable method. The ink penetrates into the microfeature array, wetting the sides and surfaces in between the microfeatures (so-called Wenzel wetting) because of the energy of impact of the ink onto the surface and because of elevated surface temperature, rather than remaining on top of the array (so-called Cassie wetting). The ink, now wetting the microfeature array and surface between the microfeatures, begins to spread outward from the point of initial placement in a manner limited by the micropillars 62 in a highly controlled and predictable manner based on the volume and spacing of the ink droplets.

The microchannels in the substrate can be used to make an entire printed electronic circuit, or only some critical portions that require narrow and/or finely-spaced features, such as component attach features and fan-out traces. If the microchannels are used to make only a part of a printed electronic circuit, the rest of the circuit can be printed using digital inkjet or another printing method. In this manner, the digital nature of inkjet can be preserved for the rest of the circuit. For instance, substrates can be imprinted with microchannels comprising component attachment features and fan-out traces designed for a particular component, and can be distributed along with that component. Subsequent manufacturing fills these microchannels with conductive ink to print the remainder of the desired circuit using a suitable printing method.

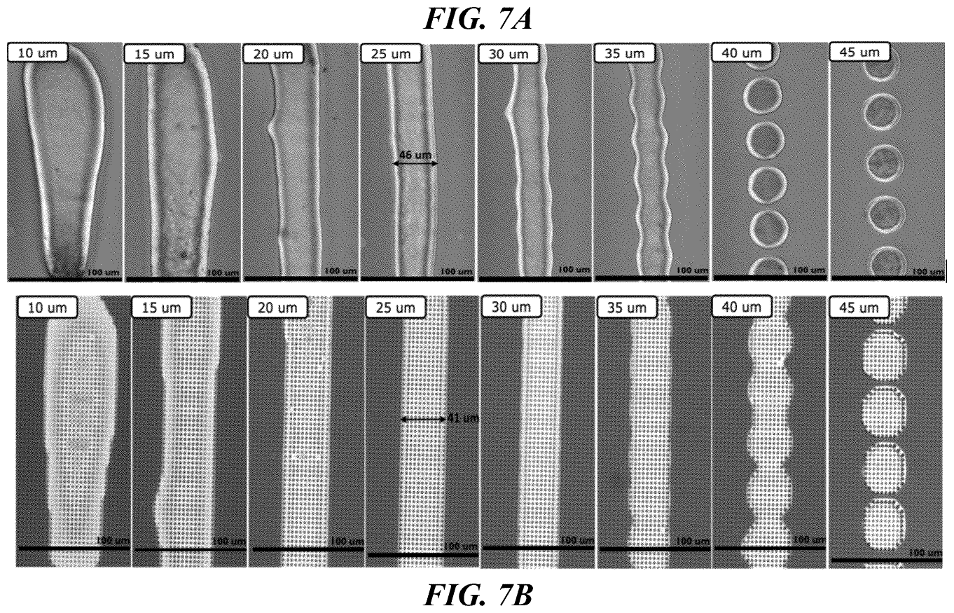

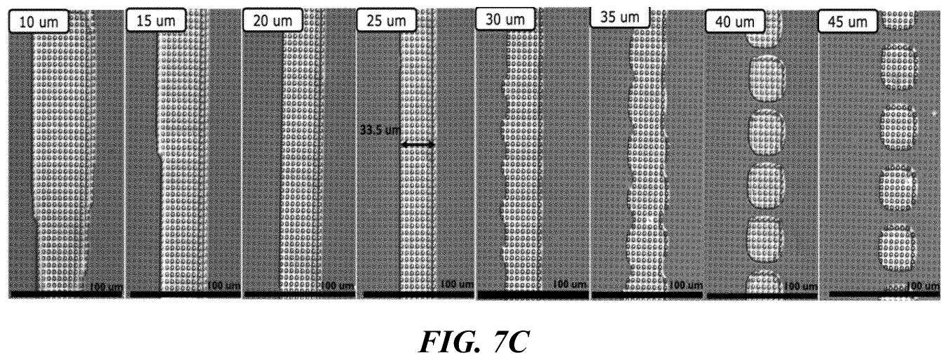

In another example, a conductive ink containing silver is employed for printing conductive traces. FIGS. 7A-7C show an effect of temperature on microfeature array printing as in FIGS. 1-4. FIG. 7A depicts a flat substrate; FIGS. 7B and 7C show ink layers deposited onto the micropillar array, such that the ink layer forms a continuous trace having a width based on a drop spacing of the deposited ink. Any suitable drop spacing may be employed; in a particular configuration the drop spacing is less than the width of the ink trace to form a controlled, consistent conductive trace. Viscosity of the liquid ink, as well as droplet volume (size) also affect flow, in addition to temperature.

Referring to FIGS. 2 and 7A-7C, silver nanoparticle ink was inkjet-printed onto a flat surface (FIG. 7A) and surfaces having two different regular arrays of microfeatures. FIG. 7B shows a microfeature array 50 of micropillars 62 that have width of 1.236 μm and spacing of 2.472 μm, and the FIG. 7C array 50 consists of micropillars that have width of 2.472 μm and spacing of 2.472 μm. The chemical composition of the flat and microfeatured surfaces is the same. The contact angle of the ink on the flat surface is approximately 32°. The same ink is printed with identical settings and conditions in all cases (7.2 pL drop volume, 9.6 μm/s drop velocity, 25 μm drop spacing), at a surface temperature of 70° C. In contrast to a room-temperature deposition at around 30° C., the higher temperature aids the controlled flow in the ink by the micropillars 62. In each case, a 1-pixel-wide line of drops is printed, and the spacing between the ink drops is varied from 10 to 45 μm.

In FIGS. 7A-7C, it can be seen that the narrowest trace on the flat surface has a width of 46 μm (FIG. 7A), while the narrowest trace of FIG. 7B and FIG. 7C have widths of 41 μm and 33.5 μm, respectively. Therefore, at this surface temperature, the microfeatures present a barrier to the continued flow of the ink and thereby confine the ink to a smaller area than would have occurred on a flat surface without microfeatures. The confinement occurs due to pinning of the ink contact line, and is a function of the inherent contact angle (i.e. the contact angle between the ink and the material surface), the geometry of the microfeature array (due to pinning of the ink at the micropillars), and the surface temperature (due to drying-induced pinning of the ink). At increased droplet spacing, around 45 um, a droplet may not meet an adjacent droplet and may need additional layers to form a continuous trace. Nonetheless, the consistency of the spreading diameter and predictable flow is seen,

During deposition, the ink, being a solvent based carrier of solids such as conductive particles, is affected by heat and evaporation to aid in “pinning”—an adherence of the ink to the substrate and termination of liquid flow. Pinning occurs with each successive layer. When applied to the micropillar array 50, a trace formed from a first ink layer having a first width results in a second ink layer having a second width less than or equal to the first width. In other words, the previously applied layer tends to define the pinning of successive layers to the same boundary and mitigate flow. FIGS. 7A-7C depict a heated substrate, such that the heated substrate heats the applied ink layers for pinning each ink layer to a boundary defined by a previous ink layer. Heating may be applied to either of the ink and substrate for enhancing the pinning effect.

A high surface temperature is therefore important during printing, to cause drying of the advancing contact line of the ink and pinning of the ink at the micropillars 62. The importance of surface temperature is clearly seen if the printing is done instead at a low surface temperature of 30° C., which results in the ink spreading out more on the micropillar surface than it would on a flat surface (opposite to the result at 70° C.). This is because the ink wicks through the micropillar array and has more time to spread in the absence of drying-induced pinning caused by high surface temperature.

Pinning increases with the filling fraction of the microfeature array. The micropillars in FIG. 7C have a larger width but same spacing (i.e. larger filling fraction) compared to those in FIG. 7B, and therefore resulted in greater pinning of the ink and confinement of the ink to a smaller region. Therefore, the confinement of the ink by the microfeatures leads to smaller minimum printed feature size (including smaller minimum trace width) and higher print resolution compared to printing on a flat surface.

Further, when compared to the printed features on the flat surface, the edges of the printed features on the microfeatured surface are precisely defined by pinning of the ink along the rows and columns of the microfeature array, leading to very straight, smooth edges with tight dimensional tolerance.

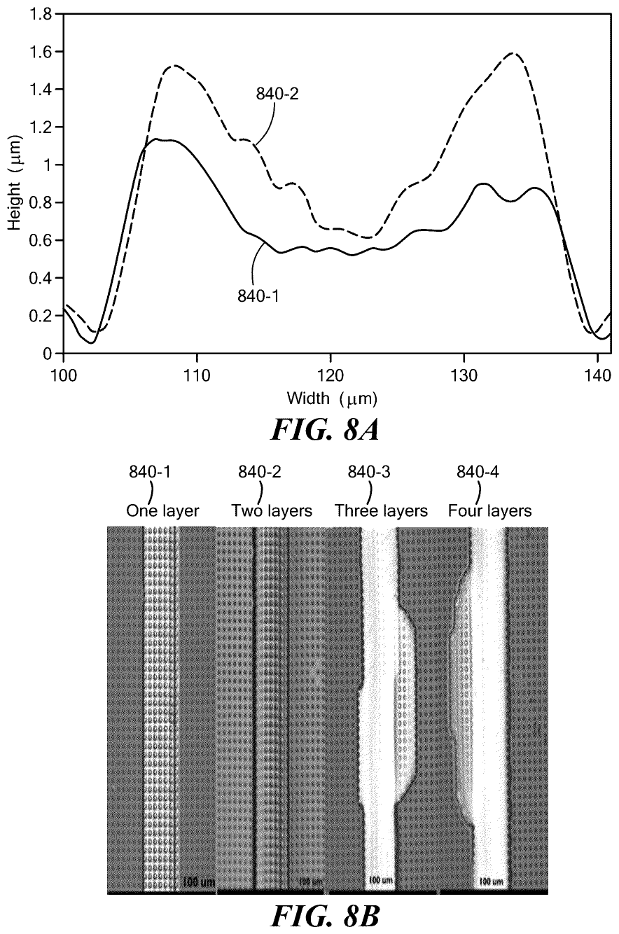

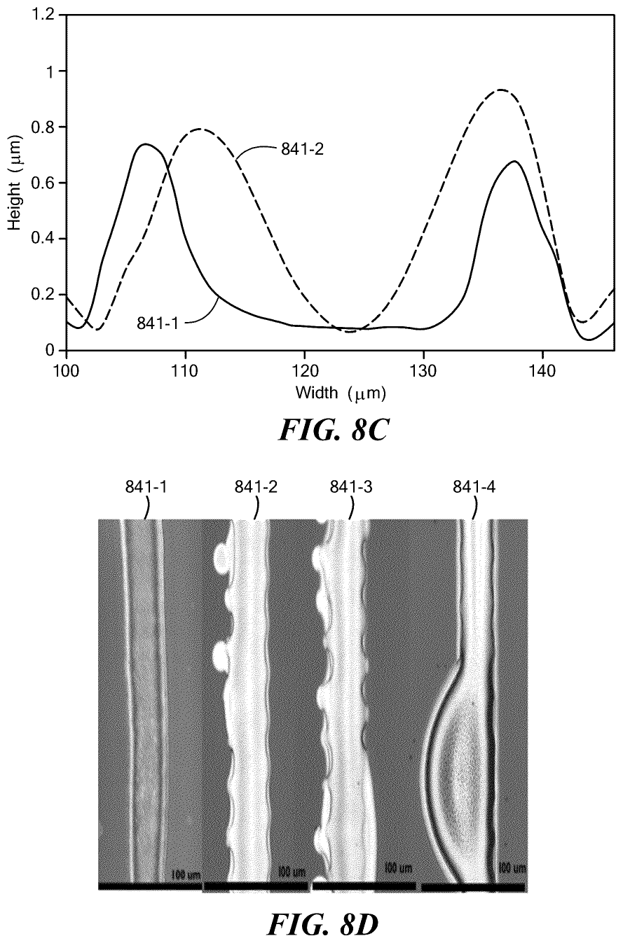

FIGS. 8A-8D show layers of silver ink forming a trace on a microfeature array. Referring to FIGS. 7A-8D, FIGS. 8A and 8B show multiple layers of silver nanoparticle ink printed at 70° C. surface temperature onto surface having micropillar array with width of 2.472 μm and spacing of 2.472 μm, similar to FIG. 7C for one layer 40-801, two layers 40-802, three layers 40-803 and four layers 40-804, for top views (FIG. 8A) and profilometry (FIG. 8B). FIGS. 8C and 8D show corresponding views of flat surface printing of 1-4 layers forming a trace 841-1 . . . 841-4.

FIGS. 8A and 8B demonstrate multiple layers of ink iteratively printed to build up additional thickness and continuing to be confined by the microfeature array 50. Specifically, 2 layers (840-2) of ink printed onto the micropillar array continue to be confined to the same width as 1 layer (840-1) of ink, and continue to form a trace with very straight edges. It is only when a 3^{rd} layer is added that the ink starts to spill out to the sides, widening the trace. In contrast, when 2 layers of ink are printed onto the flat surface, significant spilling over and bulging of the ink is observed, which greatly widens the trace.

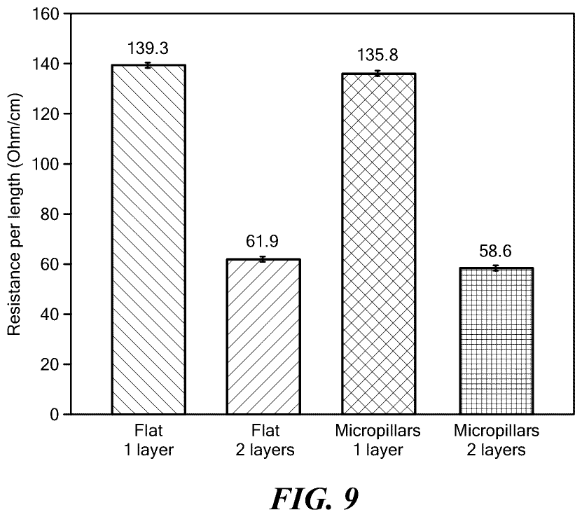

Importantly, the printed silver ink fully wets the micropillars 62 and the surface in between the micropillars, forming a continuous trace of material. The ink remains continuous (and electrically conductive in the case of conductive ink). The electrical resistance of 1-2 layers of 1 pixel-wide printed traces both on the flat surface and on the micropillar array having width of 2.472 μm and spacing of 2.472 μm were measured after annealing for 30 minutes at 130° C. As shown in FIG. 9, the resistance per unit trace length of the 1-layer traces printed on the micropillars is nearly the same as that of the 1-layer traces printed on the flat surface. Similarly, the resistance per unit trace length of the 2-layer traces printed on the micropillars is nearly the same as that of the 2-layer traces printed on the flat surface. This indicates that the large majority of the conductive silver ink forms a continuous trace in between the pillars, rather than forming a coating on top of the pillars. In fact, the resistance of the traces printed on the micropillars is slightly smaller than that of the traces printed on the flat surface, in each case. Also, the resistance of the 2-layer traces is less than half of the resistance of the 1-layer traces for both cases.

FIG. 9 shows a resistance of a trace printed as in FIGS. 8A-8D. Referring to FIGS. 8A, 8B and 9, FIG. 9 graphs electrical resistance per unit length of 1-layer and 2-layer traces of silver nanoparticle ink printed at 70° C. surface temperature onto flat surface and onto surface having micropillar array with width of 2.472 μm and spacing of 2.472 μm, after annealing for 30 minutes at 130° C.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. In a nanoimprint lithography development environment having a substrate adapted for roll to roll microfeature imprinting, a microfeature array, comprising:
a substrate adapted for nanoimprint lithography;
a first microchannel set including plurality of microchannels in the substrate extending in a first direction; and
a second microchannel set including a plurality of microchannels in the substrate extending in a second direction, the microchannels of the first set intersecting with the microchannels of the second set,
each microchannel of the plurality of microchannels in the first microchannel set and the second microchannel set having a width based on an intended width of a printed trace of ink onto the substrate.

2. The microfeature array of claim 2 wherein the width of the microchannels is based on a plurality of layers of ink deposited onto the substrate for forming the trace of the intended width.

3. The microfeature array of claim 1 further comprising an array of micropillars, each micropillar of the array of micropillars defined by an intersection of the first and second sets of microchannels.

4. The microfeature array of claim 3 wherein the first set of microchannels forms a parallel array of microchannels and the second set of microchannels forms a parallel array of microchannels, the first set of microchannels substantially perpendicular to the second set of microchannels.

5. The microfeature array of claim 1 wherein each micropillar in the array of micropillars is defined by a protruding substrate region flanked by intersecting opposing pairs of microchannels.

6. The microfeature array of claim 1 wherein each microchannel has a width and a depth, the width at least 10 times the depth.

7. The microfeature array of claim 1 wherein each microchannel in the first set of microchannels has a width and a spacing, the spacing between 0.5 and 3 times the width.

8. The microfeature array of claim 3 further comprising an ink layer, the ink layer deposited onto the micropillar array, the ink layer forming a continuous trace having a width based on a drop spacing of the deposited ink, the drop spacing less than the width of the ink trace.

9. The microfeature array of claim 3 further comprising a trace formed from a first ink layer having a first width, and a second ink layer having a second width less than or equal to the first width.

10. The microfeature array of claim 3 further comprising a trace formed from iterative application of ink layers, the trace having a height greater than a depth of the microchannels and extending proud of a flush surface defined by a top of the micropillars.

11. The microfeature array of claim 10 further comprising a heated substrate, the heated substrate heating the applied ink layers for pinning each ink layer to a boundary defined by a previous ink layer.

12. A method of printing a circuit, comprising:
forming a microfeature array on a substrate based on intersecting arrays of parallel microchannels, the substrate retaining micropillars defined by protruding substrate regions flanked by intersecting microchannels;
depositing a sequence of ink droplets onto the microfeature array based on a trace pattern, each ink droplet having a volume of ink and a spacing from adjacent ink droplets; and
confining a flow of each ink droplet to a width of the trace pattern while meeting a flow of adjacent droplets in the sequence for forming a continuous trace.

13. The method of claim 12 wherein the ink is conductive ink including conductive particles, and the flow of each ink droplet meets the flow of the adjacent droplets for forming a conductive trace.

14. The method of claim 12 further comprising confining a flow of each ink droplet based on a wetting angle of the ink with the micropillars.

15. The method of claim 14 further comprising heating the ink for pinning the ink at a boundary defined by the trace pattern.

16. The method of claim 12 further comprising printing successive passes of ink droplet sequences, each sequence defining a layer of a trace corresponding to the trace pattern, the successive passes pinning to a boundary of previous passes based on at least one of a drop size and a temperature of the ink.

17. A method of printing electronics, comprising
forming a microfeature array on a circuit substrate responsive to printed nanoparticle ink;
depositing the nanoparticle ink onto the circuit substrate based on a predetermined circuit design; and
limiting the boundaries of the deposited nanoparticle ink by the microfeatures, the microfeatures having a geometry that presents a barrier to the continued flow of the ink across the circuit substrate.

18. The method of claim 17 further comprising forming the microfeature on the circuit substrate via nanoimprint lithography.

19. The method of claim 17 wherein the microfeatures provide confinement of the deposited ink to avoid a spread of inkflow from an initial placement based on at least one of pinning of an ink contact line, a contact angle of the ink, a geometry of the microfeature array and a temperature of the circuit substrate.

20. In a nanoimprint lithography development environment having a substrate adapted for roll to roll microfeature imprinting, a microfeature array, comprising:
a substrate adapted for nanoimprint lithography;
a microchannel set including one or more microchannels in the substrate extending in a first direction,
each microchannel of the microchannel set having a width based on an intended width of a printed trace of ink onto the substrate and a depth based on an accumulated thickness of one or more layers of ink deposited in the microchannel.
